(19) United States
(12) Patent Application Publication
(10) Pub. No.: US 2016/0013369 A1
(43) Pub. Date: Jan. 14, 2016

(54) Optoelectronic Component And Method For Producing An Optoelectronic Component

(71) Applicant: OSRAM OPTO SEMICONDUCTORS GMBH, Regensburg (DE)

(72) Inventors: Kathy SCHMIDTKE, Mainburg (DE); Ion STOLL, Tegernheim (DE); Tony ALBRECHT, Bad Abbach (DE); Markus KLEIN, Penang (MY)

(73) Assignee: OSRAM OPTO SEMICONDUCTORS GMBH, Regensburg (DE)

(21) Appl. No.: 14/769,699

(22) PCT Filed: Mar. 4, 2014
(86) PCT No.: PCT/EP2014/054147

§ 371 Date: Aug. 21, 2015

(30) Foreign Application Priority Data
Mar. 12, 2013 (DE) 10 2013 102 482.3

(51) Int. Cl. H01L 33/50; H01L 33/54; H01L 33/00; H01L 33/48; H01L 33/62

(52) U.S. Cl. CPC H01L 33/502; H01L 33/483; H01L 33/62; H01L 33/005; H01L 33/54; H01L 2933/0041; H01L 2933/0066; H01L 2933/0033

(57) ABSTRACT

An optoelectronic component, comprising: a carrier (1) and a semiconductor layer sequence (20) configured for emission of electromagnetic primary radiation and arranged on the carrier (10). The semiconductor layer sequence (20) comprises a radiation main side (21) facing away from the carrier. A connecting layer is applied directly at least on the radiation main side (21) of the semiconductor layer sequence. A conversion element (40) is configured for emission of electromagnetic secondary radiation and is arranged directly on connecting layer (30), and being formed as a prefabricated body. Connecting layer (30) comprises at least one inorganic filler (31) embedded in matrix material and being formed with a layer thickness of less than or equal to 2 μm. The prefabricated body is attached to the semiconductor layer sequence by the connecting layer which is configured in order to filter out a short-wave component of the electromagnetic primary radiation.

The present invention relates to an optoelectronic component and to a method for producing an optoelectronic component.

An object to be achieved is to provide an optoelectronic component and a method for producing an optoelectronic component, which has improved stability.

According to one embodiment, the optoelectronic component comprises a carrier, and a semiconductor layer sequence which is configured for the emission of electromagnetic primary radiation and is arranged on the carrier. The semiconductor layer sequence comprises a radiation main side facing away from the carrier. The optoelectronic component comprises a connecting layer which is applied directly at least on the radiation main side of the semiconductor layer sequence. The optoelectronic component comprises a conversion element which is configured for the emission of electromagnetic secondary radiation and is arranged directly on the connecting layer, the conversion element being formed as a prefabricated body. The connecting layer comprises at least one inorganic filler embedded in a matrix material, the connecting layer being formed with a layer thickness of less than or equal to 2 μm. The prefabricated body is attached to the semiconductor layer sequence by means of the connecting layer. The connecting layer is configured in order to filter out a short-wave component of the electromagnetic primary radiation.

According to at least one embodiment of the optoelectronic component, it comprises a carrier. The carrier may for example be a printed circuit board (PCB), a ceramic substrate, a circuit board or an aluminum plate.

According to at least one embodiment, the optoelectronic component comprises a semiconductor layer sequence. The semiconductor layer sequence may be a component of a semiconductor chip. The semiconductor layer sequence is arranged over the carrier. The semiconductor layer sequence is preferably based on a III/V compound semiconductor material. The semiconductor materials used in the semiconductor layer sequence are not restricted, so long as at least some of them exhibit electroluminescence. The semiconductor layer sequence may for example comprise compounds of elements which are selected from indium, gallium, aluminum, nitrogen, phosphorus, arsenic, oxygen, silicon, carbon and combinations thereof. Other elements and additives may, however, also be used. The layer sequence with an active region may, for example, be based on nitride compound semiconductor materials. In the present context “based on nitride compound semiconductor materials” means that the semiconductor layer sequence or at least a part thereof comprises or consists of a nitride compound semiconductor material, preferably AlₙGaₘIn₁₋ₙ₋ₘN, where 0≦n≦1, 0≦m≦1 and n+m≦1. This material need not in this case necessarily have a mathematically exact composition according to the formula above. Rather, it may for example comprise one or more dopants and additional components. The formula above only indicates a simplified representation of the essential components of the crystal lattice (Al, Ga, In, N) even though these may be partially replaced and/or supplemented with small amounts of further substances.

The semiconductor layer sequence may, for example, comprise as an active region a conventional pn junction, a double heterostructure, a single quantum well (SQW) structure or a multiple quantum well (MQW) structure. Besides the active region, the semiconductor layer sequence may comprise further functional layers and functional regions, for instance p- or n-doped charge carrier transport layers, i.e. electron or hole transport layers, p- or n-doped confinement or cladding layers, buffer layers and/or electrodes and combinations thereof. Such structures relating to the active region or the further functional layers and regions are known to the person skilled in the art particularly in terms of configuration, function and structure, and will therefore not be explained in further detail here.

According to at least one embodiment, the semiconductor layer sequence comprises roughening. In particular, the roughening is part of the radiation main side of the semiconductor layer sequence.

During operation of the semiconductor layer sequence, electromagnetic primary radiation is generated in the active layer.

According to at least one embodiment, the electromagnetic primary radiation is selected from the UV and/or blue wavelength range. A wavelength of the electromagnetic primary radiation preferably lies at wavelengths of between 100 nm and 490 nm, inclusive. In particular, the wavelength range lies between 100 and 280 nm and/or 280 and 315 nm and/or 315 and 380 nm. As an alternative or in addition, the wavelength may lie between 420 and 490 nm, in particular 440 and 480 nm, inclusive.

According to at least one embodiment, the semiconductor layer sequence is a light-emitting diode, abbreviated to LED.

According to at least one embodiment, the semiconductor layer sequence comprises a first and a second electrical terminal layer. The first and second electrical terminal layers are both arranged, in particular, between the carrier and the connecting layer. The first and second electrical terminal layers may be electrodes, p-contacts, n-contacts and/or metallization layers. The first and second electrical terminal layers contact the semiconductor layer sequence. In this way, electromagnetic primary radiation can be emitted from the semiconductor chip during operation of the optoelectronic component.

According to at least one embodiment, the semiconductor layer sequence comprises a radiation main side. The radiation main side is a surface which faces toward the carrier. In particular, the radiation main side is oriented perpendicularly to a growth direction of the semiconductor layer sequence of the optoelectronic component.

According to at least one embodiment, the semiconductor layer sequence comprises a connecting layer. The connecting layer may be applied directly onto the radiation main side of the semiconductor layer sequence. In this context, “directly” means that the connecting layer is directly in mechanical and/or electrical contact with the radiation main side of the semiconductor layer sequence. There are in this case no further layers and/or elements arranged between the connecting layer and the semiconductor layer sequence. The connecting layer may be configured in order to filter out a short-wave component of the electromagnetic primary radiation. In other words, the connecting layer partially or fully absorbs short-wave components of the electromagnetic primary radiation. In this context, “short-wave electromagnetic primary radiation” means that the electromagnetic primary radiation has wavelengths from the range of from 100 nm to 490 nm, in particular from 315 to 380 nm. In this context, that the electromagnetic primary radiation is partially absorbed means that the connecting layer has a transmission of 70%, in particular >80%, in particular 85% for the electromagnetic primary radiation. By the filtering out of the short-wave component of the electromagnetic primary radiation, the main material of a conversion element subsequently arranged in the beam path can be protected against destruction or breakdown, and the ageing of the conversion element and therefore of the entire optoelectronic component can therefore be reduced.

According to at least one embodiment, the connecting layer is partially or fully arranged at least on the radiation main side of the semiconductor layer sequence. “Partially” means that the connecting layer is arranged pointwise on the radiation main side of the semiconductor layer sequence, the point regions of the connecting layer not to be in direct contact with one another. “Fully” means the formation of a homogeneous connecting layer. In particular, the homogeneous connecting layer has a uniform layer thickness.

According to at least one embodiment, the connecting layer has a layer thickness of less than or equal to 2 μm. In particular, the layer thickness is from 1 to 2 μm, inclusive. As an alternative, the connecting layer has a layer thickness of between 50 nm and 800 nm, in particular 50 and 200 nm, for example 150 nm.

According to at least one embodiment, the connecting layer comprises an inorganic filler. The inorganic filler may be configured in order to filter out the short-wave components of the electromagnetic primary radiation. In this case, the filtering or absorption of the short-wave component of the electromagnetic primary radiation may take place fully or partially. “Short-wave component of the electromagnetic primary radiation” means that the electromagnetic primary radiation has wavelengths from the UV or blue spectral range of the electromagnetic primary radiation, for example from the range of from 100 nm to 490 nm, in particular from 315 to 380 nm. In this way, degradation of the matrix material of the connecting layer and/or of the main material of the conversion element can be reduced or prevented.

According to at least one embodiment, the inorganic filler is titanium dioxide (TiO₂) or zinc oxide (ZnO). Titanium dioxide and zinc oxide may comprise doping.

According to at least one embodiment, the doping may be carried out with a substance that is selected from a group which consists of niobium (Nb), aluminum (Al) and indium (In).

The proportion of the dopant in the inorganic filler may lie between 0.1 and 5 wt %, in particular between 0.5 and 2.5 wt %, for example 0.8 wt %. The doping has a positive influence on the shape and/or position of the absorption edge of the inorganic filler.

According to at least one embodiment, the inorganic filler is selected from a group consisting of titanium dioxide (TiO₂), n-doped titanium dioxide, Al-doped titanium dioxide, zinc oxide (ZnO), n-doped zinc oxide, In-doped zinc oxide, silver iodide (AgI), gallium nitride (GaN), indium gallium nitride (InₓGa₁₋ₓN) with x<1, iron titanate (FeTiO₃) and strontium titanate (SrTiO₃). Aluminum-doped titanium dioxide has, in particular, the advantage that it reduces the photocatalytic activity. The energy band gaps in eV of the inorganic fillers are presented in the following table:

| Inorganic filler | Energy band gaps in eV |
|---|---|
| TiO₂ | 3 to 3.2 |
| n-doped titanium dioxide | <3.2 |
| ZnO | ~3.2 |
| In-doped zinc oxide | <3.2 |
| AgI | ~2.8 |
| GaN | ~3.37 |
| InₓGa₁₋ₓN | <3.37 |
| FeTiO₃ | ~2.8 |
| SrTiO₃ | ~3.4 |

According to at least one embodiment, the inorganic fillers comprise particles with a coating. The coating may comprise or be aluminum oxide (Al₂O₃) and/or silicon dioxide (SiO₂) and/or parylene. The coating may have a thickness from 2 to 20 nm, in particular from 2 to 10 nm, for example 5 nm. The photocatalytic surface activity can be reduced by the coating of the inorganic filler. Furthermore, the inorganic filler can thereby be embedded more homogeneously into the matrix material compared with an uncoated inorganic filler.

According to at least one embodiment, the inorganic filler is formed as particles. The particles may have a particle size of greater than or equal to 50 nm and less than or equal to 800 nm, in particular from 50 nm to 200 nm, inclusive, for example 100 nm.

According to at least one embodiment, the geometry of the particles is arbitrarily selectable. The particles are, for example, shape-anisotropic. In this context, shape-anisotropic means that the particle direction-dependently has a different geometrical shape, or is shaped irregularly. Shape-anisotropic means for example that the height, width and depth of the particle are different. In particular, the particles are configured in the shape of a sphere, a tube, a wire or a rod. The size of the particles lies in the nanometer range. Shape-anisotropic particles can thus conduct heat direction-dependently. If, for example, shape-anisotropic particles are arranged with their long axis transversely to the radiation main side of the semiconductor layer sequence in the connecting layer, then during operation of the optoelectronic component the heat of the optoelectronic component can be dissipated better compared with inorganic fillers which have a direction-independent geometry.

According to at least one embodiment, the inorganic filler is formed as particles, the particles being both in direct contact with the conversion element and in direct contact with the radiation main side of the semiconductor layer sequence. In other words the particle is so large that it directly touches both the conversion element and the radiation main side. Both the inorganic filler and the matrix material of the connecting layer are therefore used for fastening the conversion layer on the semiconductor layer sequence.

According to at least one embodiment, the connecting layer has a layer thickness which corresponds to the maximum diameter or the maximum length of the particle of the inorganic filler. In order to adjust a layer thickness of the connecting layer, the particle size of the inorganic filler may be selected correspondingly. Small particles may, according to one embodiment, produce small layer thicknesses of the connecting layer.

According to at least one embodiment, the inorganic filler is embedded in a matrix material. The embedding of the filler in the matrix material may, in particular, be homogeneous. The inorganic filler is in this case not bonded covalently to the matrix material. The inorganic filler may have hydroxyl groups on its surface, for example only by coating, which enter into van der Waals interactions with the matrix material.

According to one embodiment, the matrix material comprises a silicone or consists of a silicone and/or derivatives thereof. The matrix material may have a low refractive index, particularly in the case of methyl- or alkyl-functionalized silicones (n 1.39 to 1.48) and/or a high refractive index (n 1.49 to 1.59), particularly in the case of silicones with a proportion of phenyl-functionalized silicon atoms. The matrix material may comprise polysilazane (n=1.47). The matrix material may likewise be glass. The matrix material may in particular comprise or consist of a methyl-substituted silicone, for example polydimethylsiloxane, a cyclohexyl-substituted silicone, for example polydicyclohexylsiloxane, or a combination thereof. In particular, the matrix material may be a phenyl-functionalized silicone, the maximum phenyl component being 50% expressed in terms of the total component of the functionalization. The silicone may furthermore be a polyalkylarylsiloxane.

According to at least one embodiment, the connecting layer comprises a plurality of different matrix materials. In particular, the connecting element comprises different silicones. In this case, care should be taken that the silicones have a low low-molecular-weight component. In this way, it is possible to avoid stresses in the connecting layer and bending up of the corners of the connecting layer. Furthermore, a decrease in the filter properties of the connecting layer, particularly the filtering from the blue spectral range, can thereby be avoided.

According to one embodiment, the inorganic filler has a high refractive index. In particular, the refractive index is between 2 and 3.5. The inorganic filler may have an absorption edge in the range of from 344 to 442 nm (3.6 to 2.8 eV) at room temperature. The refractive index of the connecting layer is increased by the high refractive index of the inorganic filler. In this way, less total reflection takes place at the interface of the semiconductor layer sequence and the connecting layer, and the overall brightness of the optoelectronic component is therefore improved.

According to at least one embodiment, the inorganic filler has a higher refractive index than the matrix material.

According to at least one embodiment, the inorganic filler has a higher thermal conductivity than the matrix material. The thermal conductivity of the connecting layer is therefore improved by the inorganic filler. The heat which is generated in the conversion element by conversion of the electromagnetic primary radiation into the electromagnetic secondary radiation, or in the semiconductor layer sequence, can be dissipated better owing to the inorganic filler in the connecting layer.

According to at least one embodiment, the inorganic filler is present in the matrix material in a proportion of greater than or equal to 5 wt % or 10 wt %. As an alternative or in addition, the inorganic filler is present in the matrix material in a proportion of greater than or equal to 50 wt % or 12 wt %. The inorganic filler may be distributed homogeneously in the matrix material. The homogeneous distribution can be achieved by a so-called speed mixer.

As an alternative, the inorganic filler may be distributed in the matrix material with a concentration gradient. The concentration gradient in the connecting layer may, in particular, decrease from the semiconductor layer sequence in the direction of the conversion element. This means that a high proportion of inorganic filler is distributed in the matrix material close to the radiation main side of the semiconductor layer sequence. The inorganic filler can therefore absorb the short-wave component of the electromagnetic primary radiation emerging from the semiconductor layer sequence near the semiconductor layer sequence, i.e. near the chip, and therefore reduce the ageing of the matrix material of the connecting layer and/or of the main material of the conversion element.

According to at least one embodiment, the connecting layer is formed with a form fit with the radiation main side of the semiconductor layer sequence and with a form fit with the side of the conversion element facing toward the semiconductor layer sequence. The connecting layer may cover the radiation main side of the semiconductor layer sequence over its entire area. As an alternative, the connecting layer may partially cover the radiation main side of the semiconductor layer sequence. The connecting layer may be applied in liquid form onto the semiconductor layer sequence. The application may be carried out by spreading, dispensing and/or spin coating. The conversion element may subsequently be applied or pressed onto the liquid connecting layer. By the force of the weight of the conversion element and/or the pressure which is generated by the application of the conversion element during production, a homogeneous connecting layer can be produced from the liquid and partially distributed connecting layer. The liquid connecting layer may subsequently be cured. As an alternative or in addition, the connecting layer, which is for example formed very thinly, may be produced by capillary forces.

According to at least one embodiment, a plurality of semiconductor layer sequences arranged in an array, which are arranged on a circuit board or in a light engine, may be coated with the connecting layer. As an alternative, only one semiconductor layer sequence may be coated with the connecting layer.

The semiconductor chip may subsequently be provided in an optoelectronic component with a luminescent substance by volume casting, by sedimentation or spray coating.

According to at least one embodiment, the connecting layer comprising the matrix material with the inorganic filler may already be applied onto the undivided chip wafer. The semiconductor chips may subsequently be separated and installed in an LED package or chip array.

According to at least one embodiment, the connecting layer additionally covers at least a part of the side surfaces of the semiconductor layer sequence. In this context, side surfaces of the semiconductor layer sequence mean the side surfaces of the semiconductor layer sequence which are arranged transversely to the radiation main side of the semiconductor layer sequence.

According to at least one embodiment, the connecting layer protrudes beyond the side surfaces of the semiconductor layer sequence and beyond the side edges of the conversion element. Here, side edges of the conversion element refer to the side surfaces of the conversion element which are arranged transversely to the main radiation side of the semiconductor layer sequence. The connecting layer may in this case form a bead. The bead may, in particular, extend along the side surfaces of the semiconductor layer sequence and/or the side edges of the conversion element. As an alternative or in addition the bead may protrude in plan view onto the optoelectronic component beyond the side surfaces of the semiconductor layer sequence and/or the side edges of the conversion element.

According to at least one embodiment, the connecting layer comprising the inorganic filler is electrically insulating and is not configured for the electrical conduction of the optoelectronic component. The inorganic filler is electrically insulating, and the matrix material is likewise electrically insulating. The connecting layer is therefore electrically insulating and cannot be used as an electrode and/or electrical terminal layer and/or metallization layer of the optoelectronic component. The connecting layer therefore fulfills the function of fastening the conversion element from the semiconductor layer sequence and avoiding ageing of the optoelectronic component.

According to at least one embodiment, the optoelectronic component comprises a conversion element. The conversion element comprises or consists of a main material and one or more conversion substances. The main material may be a silicone. All silicones which have already been mentioned for the matrix material of the connecting layer may be envisioned. In particular, the main material of the conversion element and the matrix material of the layer are identical. In particular, the main material of the conversion element and the matrix material of the layer are a phenyl-functionalized silicone. In this way, the light output of the optoelectronic component can be achieved. The conversion element may be produced by screen printing or by means of a slit-nozzle coater.

According to at least one embodiment, the at least one conversion substance may be embedded in the main material. The embedding may be carried out by dispersion. The embedding may be carried out homogeneously or with a concentration gradient. The conversion substance is configured in order to convert electromagnetic primary radiation into electromagnetic secondary radiation with a modified, usually longer, wavelength.

The at least one conversion substance may be any material which absorbs electromagnetic radiation and converts it into radiation with a modified, usually longer, wavelength, and emits this. For example, the conversion substance may be a garnet or an orthosilicate. In particular, the conversion substance is configured for the emission of electromagnetic secondary radiation.

According to one embodiment, the conversion element is arranged directly on the connecting layer. Here, in this context, directly means direct mechanical and/or electrical contact between the connecting layer and the conversion element. There cannot in this case be any further layers and/or elements between the connecting layer and the conversion element.

According to at least one embodiment, the conversion element is formed as a prefabricated body. In particular, the conversion element is formed as a platelet, film and/or lens. In this context, “prefabricated” means that the conversion element is fully produced per se as a solid body with a given geometrical shape, and after production it is attached or fastened or bonded onto the semiconductor layer sequence by means of the connecting layer. Prefabricated also means that the conversion element is geometrically stable. In particular, the conversion element is self-supporting. In this way, conversion element can be mounted simply onto the semiconductor layer sequence by the so-called pick-and-place process.

According to at least one embodiment, the semiconductor chip or the semiconductor layer sequence may be prefabricated.

According to at least one embodiment, the conversion element may cover the entire radiation main side. As an alternative or in addition, it may protrude beyond the radiation main side. The conversion element may have a uniform layer thickness. The layer thickness may lie between 30 μm and 400 μm. In this way, a constant color locus of the optoelectronic component can be achieved.

According to at least one embodiment, the conversion element has side edges which are arranged transversely to the radiation main side. The connecting layer may be in direct contact with the side edges of the conversion element and/or with the side surfaces of the semiconductor layer sequence. The connecting layer may furthermore protrude in plan view onto the optoelectronic component beyond the side surfaces of the semiconductor layer sequence and beyond the side edges of the conversion element.

A method for producing an optoelectronic component is furthermore provided, which comprises the following method steps:
1) providing a carrier,
2) applying a semiconductor layer sequence, which is configured for the emission of electromagnetic primary radiation, onto the carrier,
3) applying a liquid connecting layer onto the semiconductor layer sequence
4) applying a conversion element, which is formed as a solid prefabricated body and is configured for the emission of electromagnetic secondary radiation, onto the connecting layer,
5) curing the connecting layer,
6) fastening the prefabricated body by means of the connecting layer on the semiconductor layer sequence, wherein method step 3) is carried out before method step 4) or
wherein method steps 3) and 4) are carried out simultaneously,
wherein the conversion element comprises a main material, in which a conversion substance is embedded,
wherein the conversion substance is configured for the emission of electromagnetic secondary radiation, and wherein the main material of the conversion element and the matrix material of the connecting layer are identical.

The connecting layer is liquid at least at the processing temperature in method step 3). Here, “liquid” means that the connecting layer is shapeable and/or not cured. The liquid connecting layer is therefore a preform of the connecting layer. At least after curing, the final connecting layer is obtained, which fastens the conversion element and the semiconductor layer sequence to one another.

In this context, a “solid prefabricated body” means that the body does not change its properties during the curing.

For the method for producing the optoelectronic component, the same definitions and comments regarding an optoelectronic component as indicated above in the description of the optoelectronic component applies.

Other advantages and advantageous embodiments and refinements of the subject-matter according to the invention will be explained in more detail below with the aid of figures and exemplary embodiments.

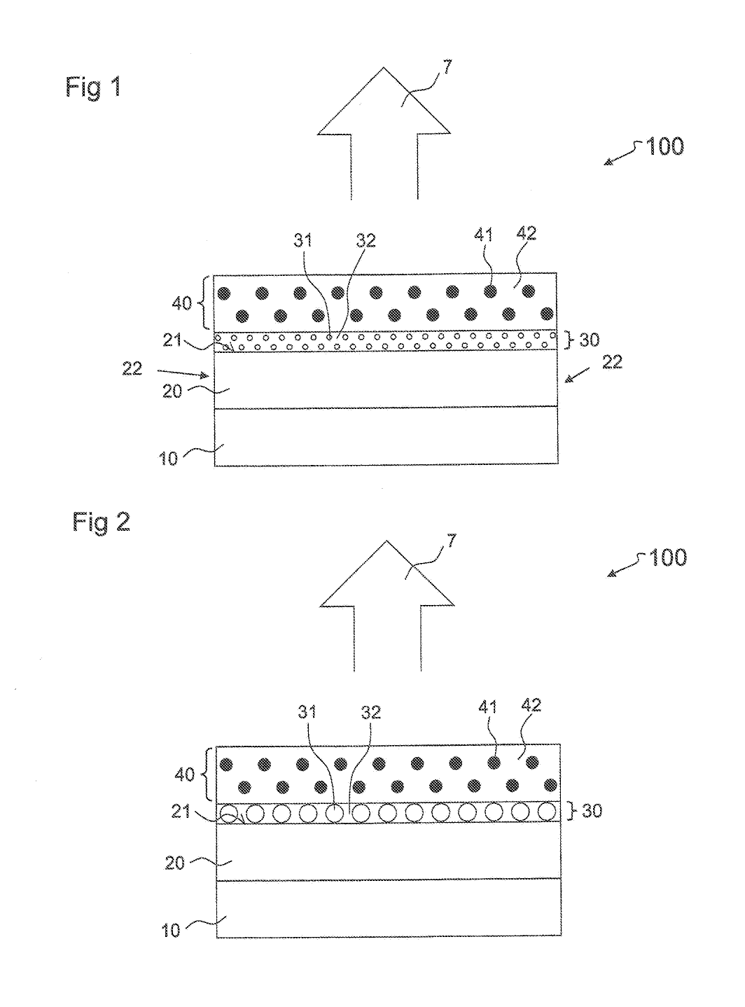

FIGS. 1 to 7 respectively show a schematic side view of an optoelectronic component according to one embodiment, and

FIG. 8 shows a schematic plan view of an optoelectronic component according to one embodiment.

In the exemplary embodiments and figures, components which are the same or have the same effect are respectively provided with the same references. The elements represented, and their size proportions with respect to one another, are not to be regarded as true to scale.

FIG. 1 shows a schematic side view of an optoelectronic component 100 according to one embodiment. The optoelectronic component 100 comprises a carrier 10. The carrier 10 may, for example, be an aluminum plate. A semiconductor layer sequence 20 is arranged on the carrier 10. The semiconductor layer sequence 20 comprises an active region, which is capable of emitting electromagnetic primary radiation.

Here and in what follows, that a layer or an element is arranged or applied “on” or “over” another layer or another element may mean that the one layer or the one element is arranged in direct mechanical and/or electrical contact on the other layer or the other element. Furthermore, it may also mean that the one layer or the one element is arranged indirectly on or over the other layer or the other element. In this case, there may then be further layers and/or elements arranged between the one layer and the other layer, or between the one element and the other element.

The semiconductor layer sequence 20 comprises a radiation main side 21. The semiconductor layer sequence 20 furthermore comprises side surfaces 22, which are arranged transversely to the radiation main side 21. A connecting layer 30 is subsequently arranged on the semiconductor layer sequence 20, or on the radiation main side 21 of the semiconductor layer sequence 20. The connecting layer 30 comprises a matrix material 32, in which inorganic fillers 31 are embedded. In particular, the connecting layer 30 is configured very thinly. For example, the connecting layer may have a layer thickness of 2 μm. In particular, the layer thickness of the connecting layer 30 is between 50 and 800 nm, in particular between 50 nm and 400 nm, and it is for example 300 nm thick. The connecting layer 30 may be formed partially or surface-wide on the radiation main side 21 of the semiconductor layer sequence 20. In this case, during the production process, the connecting layer 30 is partially applied in liquid form onto the radiation main side 21 of the semiconductor layer sequence 20. In particular, the connecting layer 30 may be partially formed in a plurality of regions on the radiation main side 21. Once the liquid connecting layer has been applied onto the radiation main side 21, a conversion element 40 is subsequently pressed onto the connecting layer 30. In other words, by the pressing, i.e. by application of pressure onto the liquid connecting layer 30, a surface-wide connecting layer 30, which extends over the entire surface of the radiation main side 21 of the semiconductor layer sequence 20, is produced from a partial connecting layer 30.

As an alternative or in addition, a part of the radiation main side 21 of the semiconductor layer sequence 20 may not be covered by the connecting layer 30, and may thus be reserved for a bonding wire 50.

The conversion element 40 comprises a main material 42, which is mixed with one or more conversion substances 41. The matrix material 32 of the connecting layer 30 and the main material 42 of the conversion element 40 may, in particular, consist of the same material. For example, the matrix material 32 and main material 42 may be a silicone. In particular, the silicone is a phenyl-functionalized silicone. Phenyl-functionalized silicones are polyorganosiloxanes which comprise as organo groups at least 1 and at most 50% phenyl radicals, expressed in terms of the total content of the organo groups. The conversion element comprising the conversion substance 41 is configured in order to convert the electromagnetic primary radiation into electromagnetic secondary radiation. In this case, an overall radiation 7, which is obtained from the sum of the electromagnetic primary radiation and the electromagnetic secondary radiation, may emerge from the optoelectronic component.

The connecting layer 30, which is arranged between the conversion element 40 and the semiconductor layer sequence 20 while directly connecting them mechanically and/or electrically, may absorb or filter at least a part of the short-wave electromagnetic primary radiation. In other words, the connecting layer 30 is configured in order to filter out UV radiation and/or blue electromagnetic primary radiation from the blue range and thus avoid ageing of the matrix material 32 and/or of the main material 42. The inorganic filler 31 is in this case, in particular, homogeneously dispersed in the connecting layer 30. The dispersing may, for example, be carried out by means of a speed mixer. By homogeneous configuration, uniform absorption of electromagnetic primary radiation can take place, and a uniform color locus can therefore be produced when the overall radiation emerges from the optoelectronic component.

FIG. 2 shows a schematic side view of an optoelectronic component 100 according to one embodiment. In contrast to the optoelectronic component 100 of FIG. 1, the layer thickness of the connecting layer 30 is formed in such a way that it corresponds at most to the maximum diameter or the maximum length of the inorganic fillers. In FIG. 2, the inorganic filler 31 is formed as spherical particles. Other shape-anisotropic geometries of the inorganic filler may, however, also be envisioned. For example, the inorganic filler may be formed as rods or tubes. The particles 31 are in direct contact with the conversion element 40 and the semiconductor layer sequence 20. In FIG. 2, the inorganic filler is distributed homogeneously. The inorganic filler 31 is in this case distributed in a plane so that the inorganic filler embedded in the matrix material 32 of the connecting layer 30 forms a monolayer. In this way, uniform absorption of the short-wave electromagnetic primary radiation of the semiconductor layer sequence 20 can be produced.

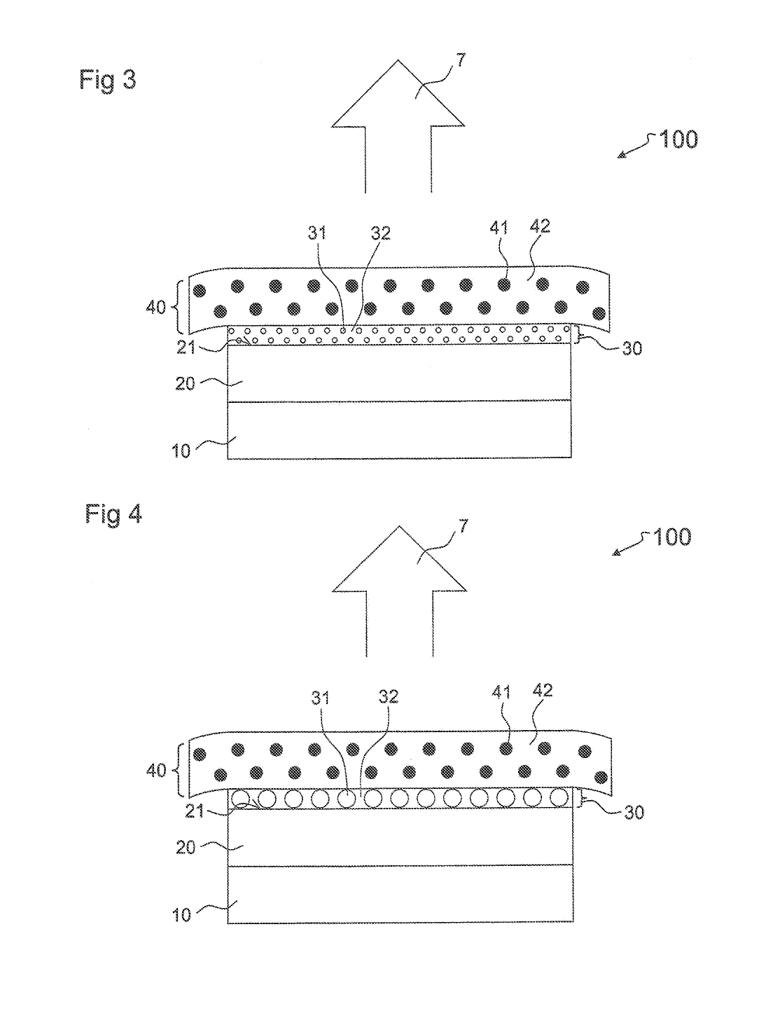

FIG. 3 shows a schematic side view of an optoelectronic component 100 according to one embodiment. In contrast to the optoelectronic component 100 of FIG. 1, the conversion element 40 protrudes beyond the side surfaces 22 of the semiconductor layer sequence and beyond the side surfaces of the connecting layer 30 and/or beyond the side surfaces of the carrier. Here, side surfaces mean the surfaces which are arranged transversely to the radiation main side 21 of the semiconductor layer sequence 20.

FIG. 4 shows a schematic side view of an optoelectronic component 100 according to one embodiment. In contrast to the optoelectronic component 100 of FIG. 2, the conversion element 40, as already described in FIG. 3, is formed in such a way that it protrudes beyond the side surfaces of the connecting layer 30, of the semiconductor layer sequence 20 and/or of the carrier 10. The connecting layer 30 is in this case formed as a monolayer.

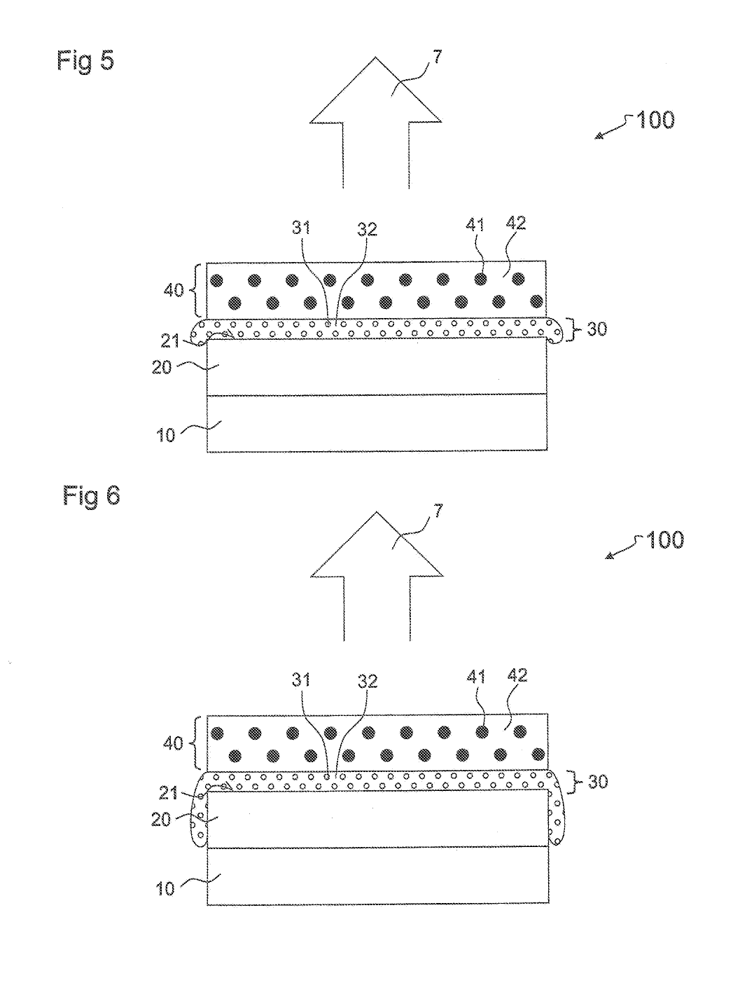

FIG. 5 shows a schematic side view of an optoelectronic component 100 according to one embodiment. The connecting layer 30 extends on the surface of the radiation main side 21 of the semiconductor layer sequence 20 and at least over a part of the side surfaces of the semiconductor layer sequence 20. The connecting layer 30 in this case protrudes beyond the side surfaces of the semiconductor layer sequence 20 and/or beyond the side edges of the conversion element 40. In this case, the connecting layer 30 forms a surface-wide homogeneous layer on the radiation main side and beyond the radiation main side a kind of bead. By application of the liquid connecting layer 30 onto the main side 21 of the semiconductor layer sequence 20 in order to fasten or attach the conversion element 40, swelling of the connecting layer beyond the side edges of the conversion element and/or side surfaces of the semiconductor layer can take place. This may, for example, be done by using large amounts of liquid connecting layer 30, for example by using large amounts of liquid material, in which the inorganic filler is embedded.

FIG. 6 shows a schematic side view of an optoelectronic component 100 according to one embodiment. In comparison with FIG. 1, the connecting layer 30 additionally also extends onto the side surfaces of the semiconductor layer sequence 20. The connecting layer 30 is therefore formed with a form fit and/or material fit on the radiation main side 21 and the side surfaces 22 of the semiconductor layer sequence 20. In this way, vertical and horizontal filtering of the short-wave electromagnetic primary radiation can be produced.

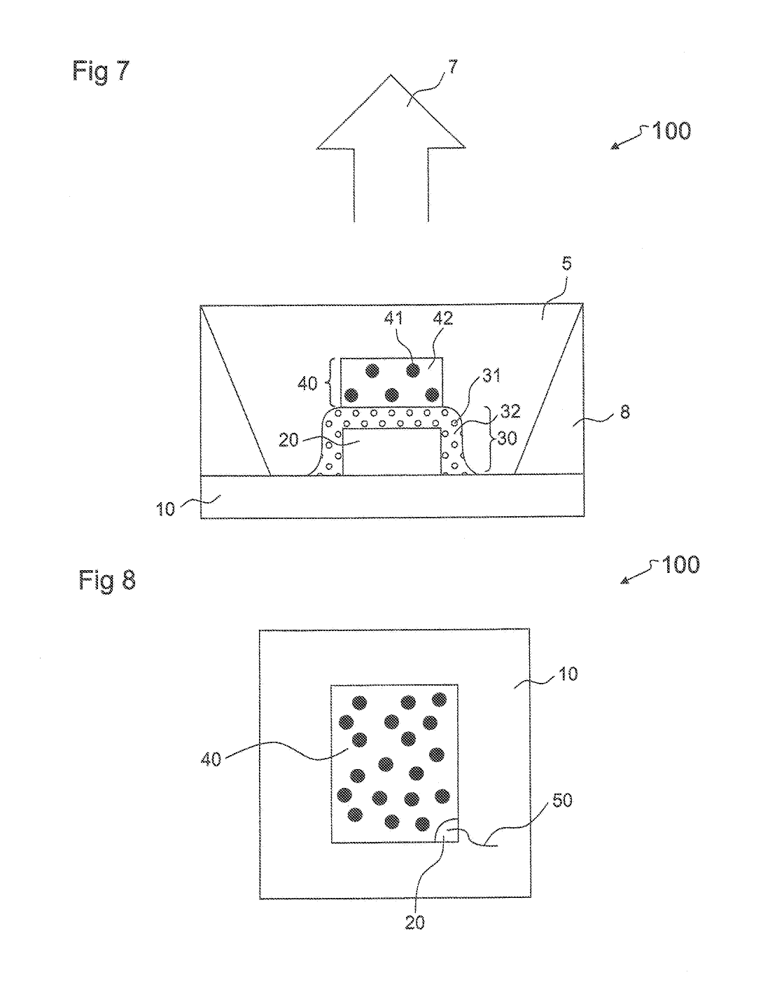

FIG. 7 shows a schematic side view of an optoelectronic component 100 according to one embodiment. The optoelectronic component 100 comprises a carrier 10. The carrier 10 in this case extends laterally beyond the side surfaces of the semiconductor layer sequence 20 and the side edges of the conversion element 40. The semiconductor layer sequence 20, the connecting layer 30 and the conversion element 40 are in this case embedded in a package 8, which comprises a recess 5. The connecting layer 30 is directly in contact with the radiation main side 21 of the semiconductor layer sequence 20 and the side surfaces of the semiconductor layer sequence 20, as well as with the surface of the carrier 10. The connecting layer 30 is therefore formed as a kind of encapsulation. In this way, the connecting layer 30 can additionally protect the semiconductor layer sequence 20 against environmental effects and absorb the shortwave component of the electromagnetic primary radiation in the direction of the radiation main side 21 as well as transversely to the radiation main side 21. The recess 5 may comprise a casting, which may for example additionally be filled with a further conversion substance. The conversion substance may likewise be configured in order to convert electromagnetic primary radiation into electromagnetic secondary radiation, usually with a longer wavelength. By the use of a plurality of conversion substances, multicolored light or white light can therefore be generated with a high efficiency.

FIG. 8 shows a schematic side view of an optoelectronic component 100 according to one embodiment. A bonding wire 50 contacts the semiconductor layer sequence 20 and the carrier 10. The conversion layer 40 and/or the layer 30 is in this case formed in such a way that they do not cover the semiconductor layer sequence 20, or the radiation main side 21 of the semiconductor layer sequence 20 in the region of the bonding wire 50.

The invention is not restricted by the description with the aid of the exemplary embodiments. Rather, the invention covers any new feature and any combination of features, which includes in particular any combination of features in the patent claims, even if this feature or this combination is not explicitly indicated per se in the patent claims or exemplary embodiments.

This patent application claims the priority of German Patent Application 102013102482.3, the disclosure content of which is hereby incorporated by reference.

1. An optoelectronic component, comprising:
a carrier;
a semiconductor layer sequence which is configured for the emission of electromagnetic primary radiation and is arranged on the carrier, wherein the semiconductor layer sequence comprises a radiation main side facing away from the carrier,
a connecting layer which is applied directly at least on the radiation main side of the semiconductor layer sequence;
a conversion element which is configured for the emission of electromagnetic secondary radiation and is arranged directly on the connecting layer, the conversion element being formed as a prefabricated body;
the connecting layer comprising at least one inorganic filler embedded in a matrix material;
the connecting layer being formed with a layer thickness of less than or equal to 2 μm;
the prefabricated body being attached to the semiconductor layer sequence by the connecting layer; and,
the connecting layer being configured in order to filter out a short-wave component of the electromagnetic primary radiation.

2. The optoelectronic component according to claim 1, wherein the inorganic filler is TiO₂ or ZnO, and TiO₂ or ZnO comprises doping.

3. The optoelectronic component according to claim 2, wherein the doping is selected from a group consisting of Nb, Al and In.

4. The optoelectronic component according to claim 1, wherein the inorganic filler comprises a proportion of greater than or equal to 5 wt % and less than or equal to 50 wt % in the matrix material.

5. The optoelectronic component according to claim 1, wherein the inorganic filler is selected from a group consisting of TiO₂, n-doped TiO₂, Al-doped TiO₂, ZnO, n-doped ZnO, In-doped ZnO, AgI, GaN, InₓGa₁₋ₓN, SrTiO₃ and FeTiO₃.

6. The optoelectronic component according to claim 1, wherein the inorganic filler is formed as particles, the particles having a particle size of greater than or equal to 50 nm and less than or equal to 800 nm.

7. The optoelectronic component according to claim 1, wherein the inorganic filler is formed as particles, the particles being both in direct contact with the conversion element and in direct contact with the radiation main side of the semiconductor layer sequence.

8. The optoelectronic component according to claim 1, wherein the conversion element comprises a main material in which a conversion substance is embedded, the conversion substance being configured for the emission of electromagnetic secondary radiation, and wherein the main material of the conversion element and the matrix material of the connecting layer being identical.

9. The optoelectronic component according to claim 1, wherein the connecting layer comprising the inorganic filler is electrically insulating and is not configured for the electrical conduction of the optoelectronic component.

10. The optoelectronic component according to claim 1, wherein the connecting layer is formed with a form fit with the radiation main side of the semiconductor layer sequence and with a form fit with the side of the conversion element facing toward the semiconductor layer sequence.

11. The optoelectronic component according to claim 1, wherein the connecting layer additionally covers at least a part of the side surfaces of the semiconductor layer sequence.

12. The optoelectronic component according to claim 1, wherein the connecting layer protrudes beyond the side surfaces of the semiconductor layer sequence and beyond the side edges of the conversion element.

13. The optoelectronic component according to claim 1, wherein the electromagnetic primary radiation is selected from the UV and/or blue wavelength range.

14. The optoelectronic component according to claim 1, wherein the connecting layer has a layer thickness which corresponds to the maximum diameter of the particles of the inorganic filler.

15. The optoelectronic component according to claim 1, wherein a first and a second terminal layer are arranged between the carrier and the connecting layer.

16. A method for producing an optoelectronic component according to claim 1, comprising, having the following method steps:
1) providing a carrier;
2) applying a semiconductor layer sequence, which is configured for the emission of electromagnetic primary radiation, onto the carrier;
3) applying a liquid connecting layer onto the semiconductor layer sequence;
4) applying a conversion element, which is formed as a solid prefabricated body and is configured for the emission of electromagnetic secondary radiation, onto the connecting layer;
5) curing the connecting layer;
6) fastening the prefabricated body by means of the connecting layer on the semiconductor layer sequence;
wherein method step 3) is carried out before method step 4) or
wherein method steps 3) and 4) are carried out simultaneously,
wherein the conversion element comprises a main material, in which a conversion substance is embedded, and
wherein the conversion substance is configured for the emission of electromagnetic secondary radiation,
and wherein the main material of the conversion element and the matrix material of the connecting layer are identical.
